(19) United States
(12) Patent Application Publication
(10) Pub. No.: US 2006/0234511 A1
(43) Pub. Date: Oct. 19, 2006

(54) Method for forming a semiconductor device including a plasma ashing treatment for removal of photoresist

(75) Inventor: Masahiko Ohuchi, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/404,928

(22) Filed: Apr. 17, 2006

(30) Foreign Application Priority Data
Apr. 19, 2005 (JP) 2005-120610

(51) Int. Cl. H01L 21/311

(52) U.S. Cl. 438/702

(57) ABSTRACT

A method for forming a cylindrical capacitor having a metal-nitride bottom electrode, capacitor insulation film and a top electrode in a DRAM device includes the step of forming a photoresist film on the bottom electrode in a cylindrical hole, removing the photoresist film by using a plasma ashing treatment using non-oxygen gas, and consecutively forming the insulation film and the top electrode on the bottom electrode. The plasma ashing treatment uses a bias power for accelerating the plasma gas into the cylindrical trench.

### TECHNICAL FIELD

The present invention relates to a method for forming a semiconductor device including a plasma ashing treatment for removal of photoresist and, more particularly, to a method suitably used for forming a MIM (Metal-Insulator-Metal) capacitor having a cylindrical structure in a semiconductor device.

### BACKGROUND ART

A DRAM device has an increasing number of memory cells by employing a reduced design rule. The reduced design rule inevitably reduces the occupied area of each memory cell, and thus requires a reduced occupied area for a stacked capacitor used in the memory cell without reducing the capacitance thereof. A cylindrical capacitor is generally used as the stacked capacitor for storing data in a memory cell, for achieving a reduced occupied area and yet a larger capacitance.

FIG. 10 shows a conventional cylindrical capacitor, such as described in Patent Publication JP-2002-110674A. The cylindrical capacitor 36 includes a bottom electrode 30 formed on bottom and side wall of a cylindrical hole 29 formed in a thick insulator film 28, a capacitor insulation film 32 formed thereon and a top electrode 33 opposing the bottom electrode 30 with an intervention of the capacitor insulation film 32.

In manufacture of the cylindrical capacitor 36, a conductive film configuring the bottom electrode 30 is deposited on the entire surface including the surface of the cylindrical hole 29, followed by embedding photoresist within the cylindrical hole 29 on the conductive film. A top portion of the conductive film on the top surface of the insulator film 28 is etched-back, the photoresist embedded within the cylindrical hole 29 is then removed, and the capacitor insulation film 32 and top electrode 33 are consecutively deposited thereon.

As the conventional cylindrical capacitor, a MIS (Metal-Insulator-Semiconductor) capacitor is generally used, wherein the bottom electrode is made of polysilicon. In the MIS capacitor, removal of the photoresist is performed by a plasma-enhanced ashing treatment (referred to as plasma ashing treatment hereinafter) using an oxygen-containing gas such as O₂, O₃, H₂O, N₂O and CH₃OH. The plasma ashing treatment causes the surface of the bottom electrode to be oxidized and form a silicon oxide film thereon. The silicon oxide film can be selectively removed using an etchant.

Recently, instead of the MIS capacitor, a MIM capacitor is employed as the cylindrical capacitor for increasing the capacitance of the cylindrical capacitor. The MIM capacitor includes, for example, a bottom electrode made of metal nitride such as TiN, a capacitor insulation film made of AlOx and a top electrode having a two-layer structure including a TiN film and a tungsten (W) film.

The capacitance C of the capacitor is generally expressed by:
C=ε×S/d,
where ε, S and d are the dielectric constant, the area of the electrodes and the thickness of the capacitor insulation film (or distance between the electrodes), respectively. In the MIM capacitor, the bottom electrode is less oxidized compared to the bottom electrode in the MIS capacitor, to assure a smaller distance between the electrodes. This increases the capacitance of the MIM capacitor as compared to the MIS capacitor. The MIM capacitor is described in Patent Publication JP-2004-247559A, for example.

It is noted by the inventor that the plasma ashing treatment in the manufacture of the MIM capacitor for removing the photoresist may involve a reduction in the capacitance thereof due to the high activity of the oxygen-containing gas, which generates an oxide film such as a TiOx film on the surface of the bottom electrode. In this case, there is no effective technique for removing the TiOx film from the surface of the bottom electrode in the MIM capacitor.

### SUMMARY OF THE INVENTION

In view of the above, it is an object of the present invention to provide a method for forming a semiconductor device including a MIM capacitor having a higher capacitance by suppressing the oxidation of the bottom electrode in the plasma ashing treatment.

The present invention provides a method for manufacturing a semiconductor device including the steps of: forming an insulation film on a surface of a semiconductor substrate; forming a trench in the insulation film; forming a metal nitride film on the insulation film including a surface of the trench; forming a photoresist film at least within the trench on the metal nitride film; removing a portion of the metal nitride film on the insulation film; and removing the photoresist film by using a plasma-enhanced ashing treatment using plasma of a non-oxygen gas including therein no oxygen.

In accordance with the method of the present invention, the non-oxygen gas in the ashing treatment prevents oxidation of the bottom electrode, thereby suppressing reduction in the film quality of the metal nitride film.

It is preferable that the non-oxygen gas include N₂, NH₃, H₂ or a mixture of N₂ and H₂. N₂ is most preferable, for reducing the number of crystal defects in the underlying metal nitride film. The reduction of the crystal defects improves the interface between the bottom electrode and the capacitor insulation film, if used in a MIM cylindrical capacitor. This improves the film quality of the capacitor insulation film.

It is also preferable that the non-oxygen gas be accelerated toward the surface of the semiconductor substrate in a direction normal thereto in the plasma-enhanced ashing treatment. This allows the plasma to effectively reach the bottom portion of the trench, suppressing the occurrence of residues of photoresist. In such a case, it is also preferable that the non-oxygen gas is accelerated using a bias power of 150 watts or above.

The trench may be a cylindrical hole having an aspect ratio of 15 or above. The metal nitride film and the insulation film may be used as the bottom electrode and the capacitor insulation film, respectively, in a capacitor, which has a top electrode on the capacitor insulation film.

It is also preferable that the method further includes, succeeding to the photoresist removing step, the steps of cooling the semiconductor substrate down to a temperature of 100 degrees C. or lower, and exposing metal nitride film to an atmospheric air. These steps further suppress oxidation of the metal nitride film.

It is also preferable that the metal nitride film includes one of TiN, TaN and WN. In this case, the method further includes, between the metal nitride film forming step and the photoresist film forming step, the step of forming a metal oxide film on the metal nitride film. The metal nitride film is less liable to oxidation compared other conductive materials. The metal oxide film may include at least one of Al₂O₃, HfO₂, HfAlO and barium titanate. The method of the present invention may be suitably used to form a MIM capacitor.

### BRIEF DESCRIPTION OF THE DRAWINGS

FIG. 1A is a sectional view of a DRAM device manufactured by a method according to an embodiment of the present invention.

FIG. 1B is a sectional view of the DRAM device of FIG. 1A taken along line B-B in FIG. 1A.

FIGS. 2 to 7 are sectional views showing the consecutive steps of the method of the embodiment, the consecutive steps succeeding to the step shown in FIGS. 1A and 1B.

FIG. 8 is a sectional view of a plasma ashing system used in the method of the embodiment.

FIG. 9 is a graph showing the relationship between the bias power and the ashing rate in the method of the embodiment.

FIG. 10 is a sectional view of a conventional DRAM device in a step of manufacture thereof.

FIG. 11 is a sectional view schematically showing the defect in the conventional technique.

### PREFERRED EMBODIMENT OF THE INVENTION

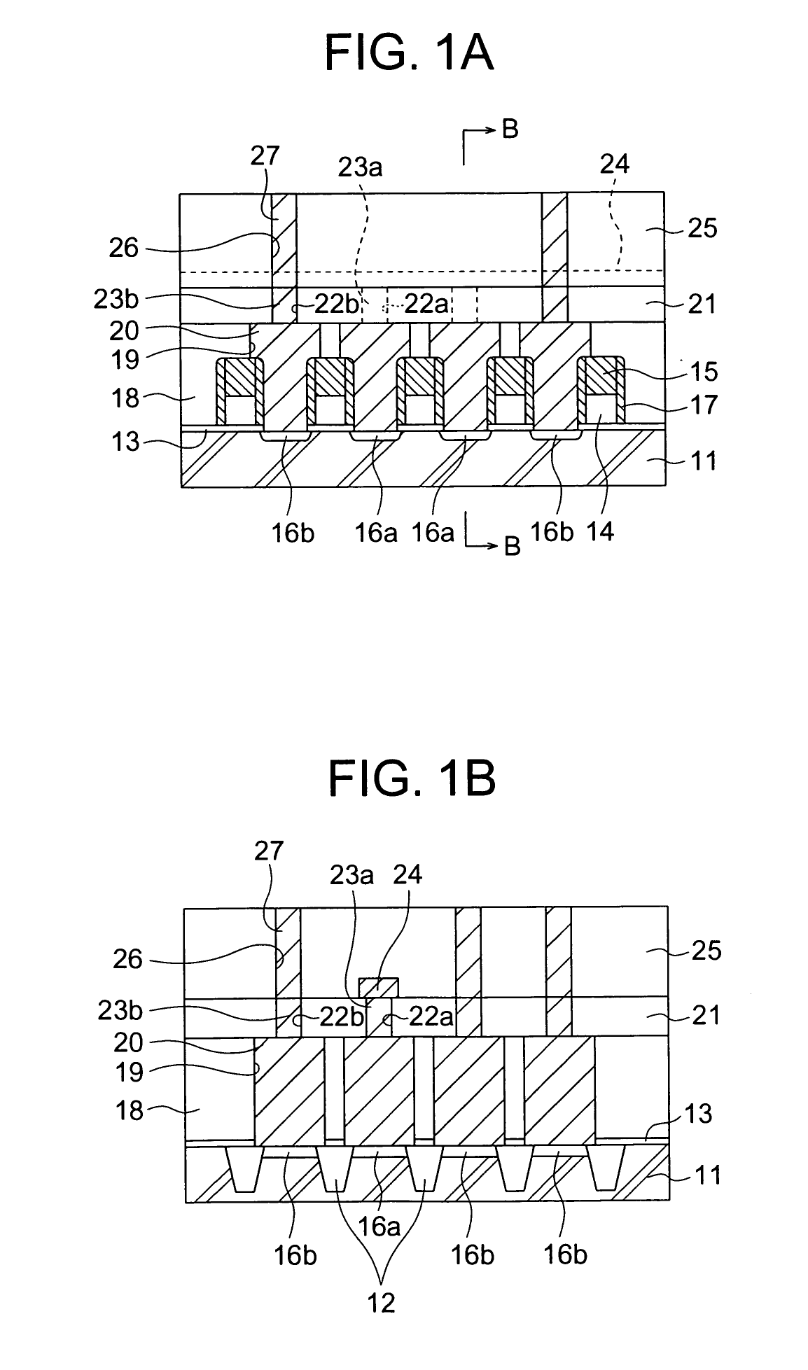

Now the present invention is described in more detail with reference to accompanying drawings based on a preferred embodiment thereof. FIG. 1A shows a step in a fabrication process for manufacturing a semiconductor device according to the embodiment of the present invention, which is configured as a DRAM device. FIG. 1B is a sectional view taken long line B-B in FIG. 1A.

In fabrication of the DRAM device, as shown in FIGS. 1A and 1B, an element isolation film 12 is formed in an isolation trench formed on the surface of a silicon substrate 11, thereby isolating the area of the silicon substrate 11 into a plurality of elongate element forming regions. Subsequently, the surface of the silicon substrate 11 is oxidized using a thermal oxidation technique, thereby forming a gate insulation film 13 made of SiO₂. Thereafter, materials for the gate electrode 14 and a Si₃N₄ film 15 are consecutively deposited on the gate insulation film 13 by using a CVD (Chemical Vapor Deposition) technique. The gate electrode 14 may include a metallic film formed using a PVD (Physical Vapor Deposition) technique. For example, the gate electrode 14 may include an amorphous silicon film, tungsten (W) film and a tungsten nitride (WN) film, as viewed from the bottom thereof.

A photoresist film (not shown) is then formed on the Si3N4 film 15, and then patterned using a photolithographic and etching technique to form a photoresist mask having a gate electrode pattern. The Si3N4 film 15 is then patterned using an anisotropic etching technique using the photoresist mask as an etching mask, thereby forming a hard mask 15. Another anisotropic etching step is then performed using the hard mask 15 as an etching mask, thereby patterning the materials for the gate electrode 14 to form the gate electrode 14. In this embodiment, as viewed in the vertical direction, the elongate element forming regions cross the gate electrodes 14 at an angle of 45 degrees therebetween.

Subsequently, ion-implantation is performed using the hard mask 15 as an implantation mask, thereby forming source/drain diffused regions 16a and 16b. The gate insulation film 13, gate electrode 14, source/drain diffused regions 16a and 16b configure a MOSFET. Thereafter, a Si3N4 film is deposited on the entire surface, followed by etch back thereof to form a side-wall film 17 on both sides of the gate electrode 14 and the hard mask 15.

Subsequently, a BPSG (Boronic Phosphoric Silicate Glass) film 18 is deposited on the entire surface by using a CVD technique, followed by a thermal annealing step at a high temperature. The thermal annealing step fills the narrow gap formed between adjacent gate electrodes 14 with the BPSG film 18. Thereafter, an etching process is performed to form contact holes 19 through the BPSG film 18 and gate insulation film 13 down to the source/drain diffused regions 16a and 16b. The contact holes 19 are then filled with polysilicon to form contact plugs 20 therein.

A SiO₂ film 21 is then deposited on the BPSG film 18, followed by forming through-holes 22a, 22b exposing the top of the contact plugs 20. The through-holes 22 is then filled with tungsten after covering the inner surface of the through-holes 22 with a TiN film, thereby forming via-plugs 23a, 23b. The via-plugs 23a are connected to the respective source diffused regions 16a via the contact plugs 20, whereas the plugs 23b are connected to the respective drain diffused regions 16b via the contact plugs 20.

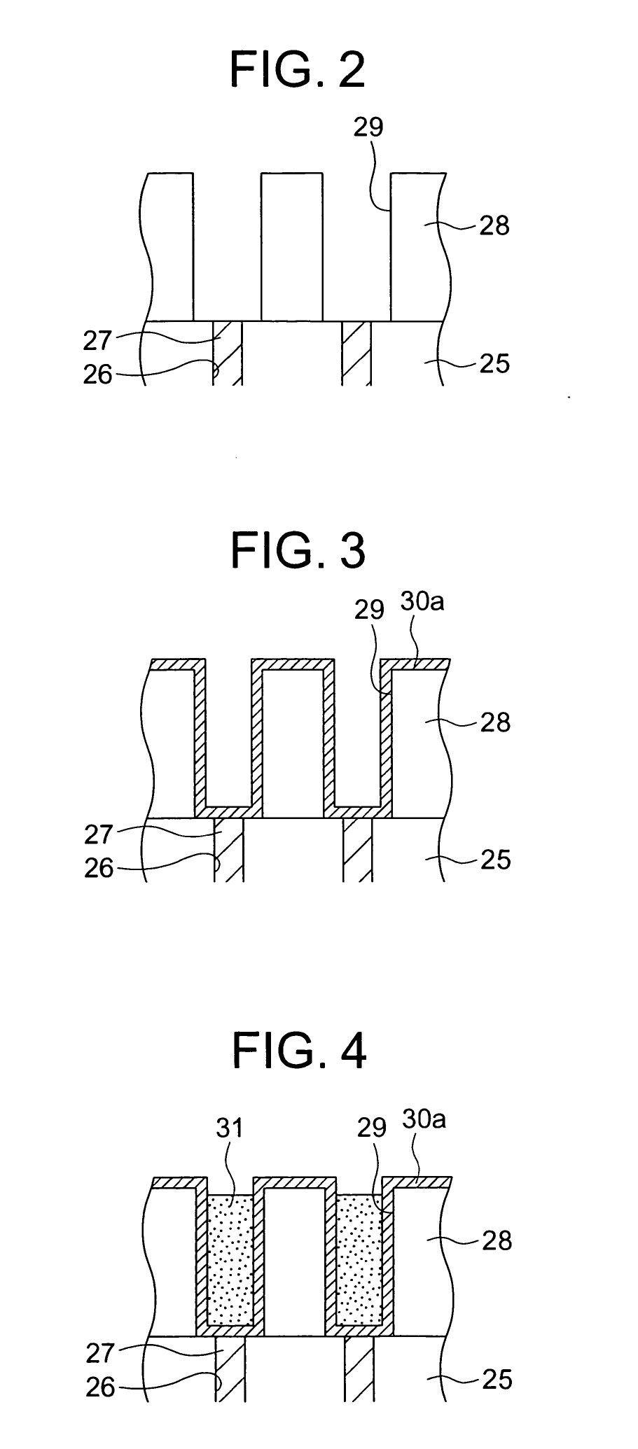

Subsequently, tungsten bit lines 24 are formed on top of the via-plugs 23a and the SiO₂ film 24, followed by forming another SiO₂ film 25. Through-holes 26 are formed in the another SiO₂ film 25, and filled with polysilicon to form via-plugs 27 therein. Thus, the structure shown in FIGS. 1A and 1B are obtained. Succeeding steps are consecutively shown in FIGS. 2 to 7.

A Si₃O₄ film (not shown) having a thickness of 50 to 100 nm is then formed on the SiO₂ film 25, followed by depositing thereon another SiO₂ film 28 up to thickness of 3000 nm by using a plasma-enhanced CVD technique. The SiO₂ film 28 has a thickness equal to the desired depth of the cylindrical holes.

Subsequently, an amorphous carbon film (not shown) is deposited up to a thickness of 600 to 1000 nm on the SiO2 film 28, followed by depositing thereon a cap film including a 20-nm-thick SiON film and a 80-nm-thick SiO₂ film. The cap film has a total thickness of about 100 nm. A photoresist mask having a pattern for the cylindrical holes is then formed on the SiO₂ film of the cap film.

Subsequently, an anisotropic etching process is conducted using the photoresist mask to pattern the cap film and the amorphous carbon film, thereby forming a hard mask. Thereafter, another anisotropic etching is conducted using the hard mask to pattern the SiO₂ film 28, thereby forming the cylindrical holes 29 therein. In this etching, the Si₃O₄ film formed on the SiO₂ film 25 is used as an etch stopper. The hard mask and residues after the etching are then removed as by ashing or cleaning, as shown in FIG. 2.

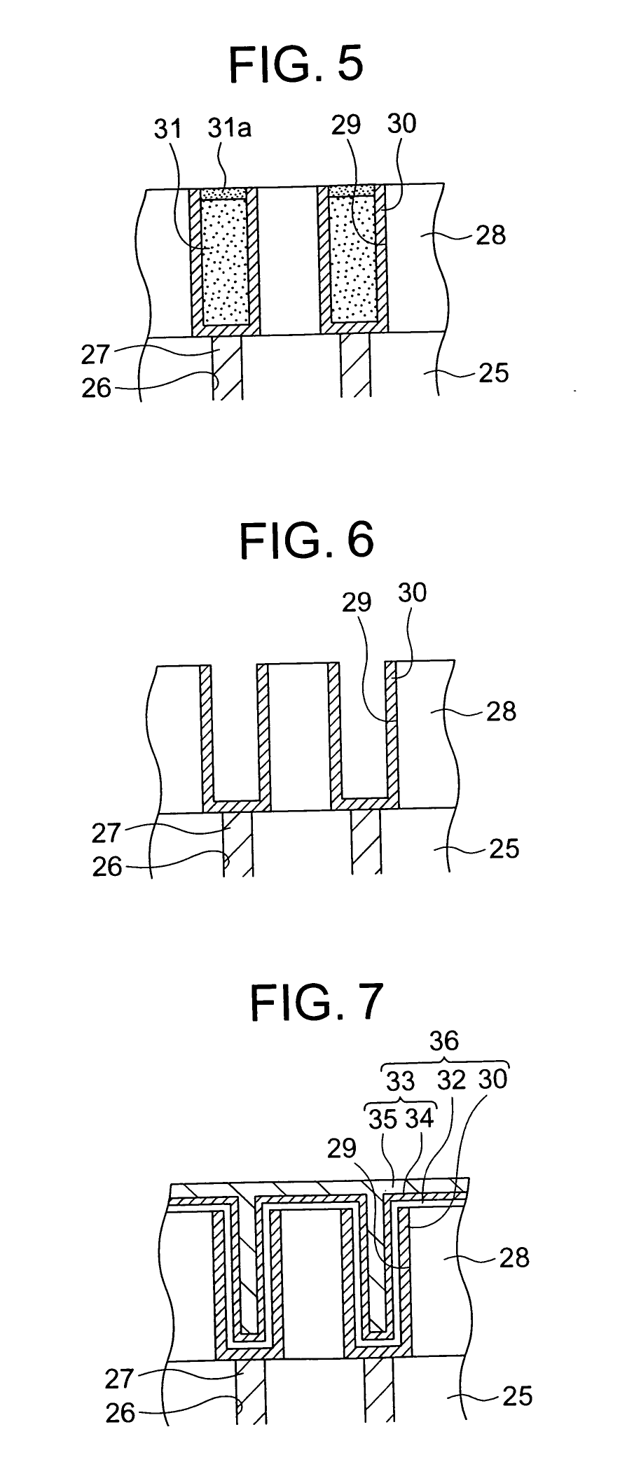

Thereafter, as shown in FIG. 3, a TiN film 30a having a uniform thickness is then formed on the entire surface including the bottom and side wall of the cylindrical holes 29 by using a CVD technique. In an alternative, a metal nitride film such as a TaN film or WN film may be formed instead. Subsequently, as shown in FIG. 4, photoresist 31 is embedded in the cylindrical holes 29 on the TiN film 30a, followed by etching a portion of the TiN film 30a on the SiO2 film 28 by using an anisotropic dry etching, thereby forming the bottom electrode 30. In this anisotropic dry etching, the top portion 31a of the photoresist 31 is hardened, as shown in FIG. 5.

Subsequently, as shown in FIG. 6, the photoresist 31 is removed from the internal of the cylindrical holes 29 by a plasma ashing treatment using non-oxygen gas, which includes therein no oxygen. In this embodiment, a mixture of N₂ and H₂ gases at flow rates of 500 sccm and 15 sccm, respectively, is supplied as the non-oxygen gas to the ashing system. The internal pressure of the ashing system is maintained at 1 Torr. The plasma of the non-oxygen gas is accelerated in the direction normal to the surface of the silicon substrate 11. The plasma etching treatment uses a source power of 3000 watts for generating plasma in the plasma system, and a bias power of 180 watts for acceleration of the plasma. The substrate temperature is maintained at 250 degrees C.

FIG. 8 shows an ashing system which can be used in the above process. The ashing system 40 is of a surface-wave plasma-source (SWP) type, and includes a chamber 41 having a gas inlet 42 and a gas outlet 43, which is connected to a vacuum pump 44 for evacuation of the chamber 41. The arrow 45 indicates the direction of gas flow.

Chamber 41 receives therein a susceptor 46 on which the silicon wafer (or silicon substrate) 11 is mounted, and a top electrode 47 opposing the silicon wafer on the susceptor 46. The susceptor 46 receives therein a flat bottom electrode 48 and a heater (not shown). The top electrode 47 is made of a dielectric substance such as AlN or quartz, whereas the bottom electrode 48 is made of a metal such as aluminum. Both the electrodes 47 and 48 are of a flat type and connected to power sources 49 and 50, respectively.

During the ashing process, gas is fed to the chamber 41 through the gas inlet 42, and power sources 49 and 50 supply high-frequency electric powers to the electrodes 47 and 48, respectively. A stationary electromagnetic wave is generated within the top electrode 47, which emits therefrom an electromagnetic wave to excite the gas and thereby generate plasma 51 in the vicinity of the surface of the top electrode 47. The voltage applied between the top electrode 47 and the bottom electrode 48 accelerates the movement of plasma 51 in the direction normal to the surface of the silicon wafer 11. The heater may be used to heat the silicon wafer 11.

After the plasma ashing treatment is completed and the substrate temperature falls down to 100 degrees C. or lower, the silicon wafer 11 is exposed to an atmospheric ambience. This prevents oxidation of the bottom electrode 30 which may be caused by the atmospheric air. Thereafter, an organic cleaning solution such as amine is used to remove residues of the photoresist left on the bottom electrode 30 and SiO₂ film 28, followed by cleaning the surface of the bottom electrode 30 as by using hydrofluoric acid. Subsequently, an Al₂O₃ film is deposited as the capacitor insulation film 32. In an alternative, a metallic oxide film such as HfO₂ film, HfAlO film, or barium titanate film may be used instead.

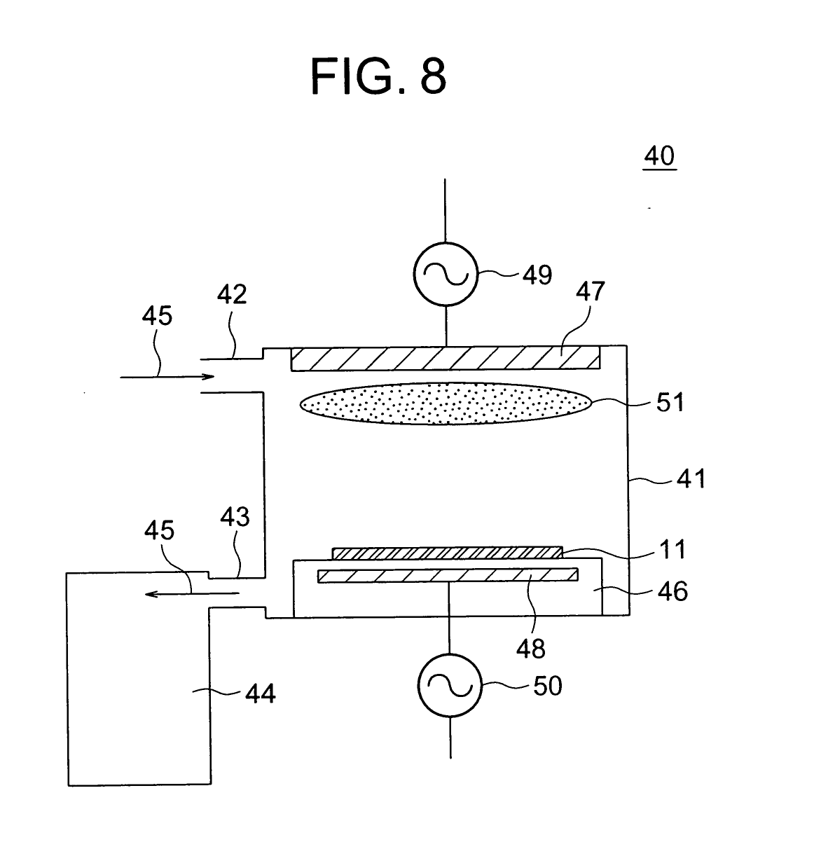

Thereafter, a TiN film 34 is deposited by using a CVD technique on the capacitor insulation film 32, followed by depositing a tungsten film on the entire surface including the internal of the cylindrical hole 29 by using a PVD technique. The TiN film 34 and tungsten film 35 configure the top electrode 33. Thus, capacitors 36 configured by the bottom electrode 30, capacitor insulation film 32 and top electrode 33 can be obtained, as shown in FIG. 7.

In the above embodiment, the plasma ashing treatment using non-oxygen-gas plasma prevents oxidation of the TiN bottom electrode 30 to thereby suppress reduction of the capacitance of the cylindrical capacitor. The N₂ gas in the plasma ashing treatment allows the surface of the bottom electrode 30 made of TiN to be nitrified, thereby reducing defects on the surface of the bottom electrode 30. This improves the quality of the interface between the bottom electrode 30 and the capacitor insulation film 32, thereby improving the insulating performance of the capacitor insulation film 32.

The conventional plasma ashing treatment, which does not use acceleration of the plasma gas, takes a long time for removing the photoresist in the cylindrical hole if non-oxygen gas is used in the ashing, especially in the case of the cylindrical holes having an aspect ratio of 15 or above. The term “aspect ratio” as used herein is defined by the ratio of the depth to the width of the holes.

FIG. 11 shows the problem encountered in the conventional plasma ashing treatment in the case of a cylindrical hole 29 having an aspect of 15 or above, wherein polymer residues 37 are attached onto the bottom electrode 30 due to insufficient function of the plasma gas. The plasma ashing treatment in the embodiment using acceleration of the plasma gas allows the plasma gas to reach the bottom of the cylindrical holes 29 having such a high aspect ratio, thereby solving the problem as shown in FIG. 11.

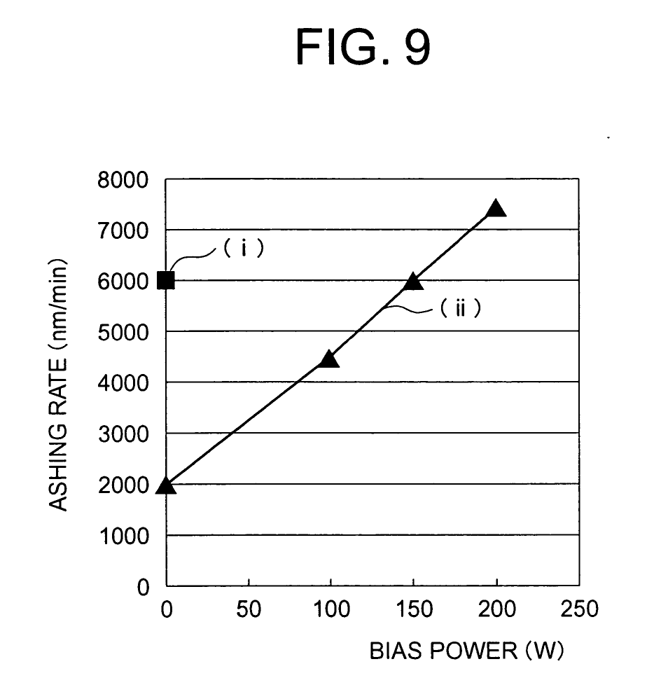

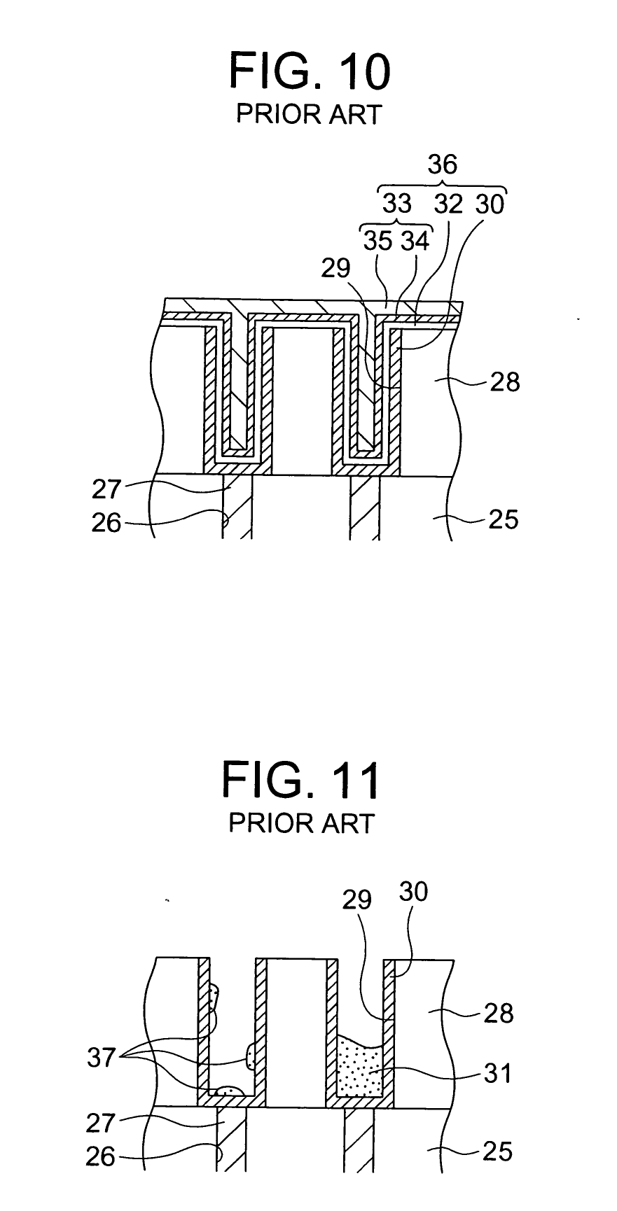

FIG. 9 shows the relationship between the bias power and the ashing rate, wherein curve (i) represents the case of using O₂ plasma and curve (ii) represents the case of using N₂ plasma. The N₂-gas plasma has an ashing rate around one-third of the ashing rate of the O₂-gas plasma if the bias power is zero watt. However, as understood from FIG. 9, a bias power improves the ashing rate of the N₂-gas plasma, wherein a bias power of 150 watts in the N₂-gas plasma ashing treatment achieves an ashing rate higher than that of the O₂-gas plasma at a bias power of zero watt.

It is generally considered that the relationship between the ashing rates in the case of using an oxidation gas other than the O₂ and the case of a non-oxygen gas other than the N₂ is similar to the relationship between the ashing rates in the case of using O₂ and the case of using N₂, as described heretofore. Thus, if a non-oxygen gas other than N₂ is to be used, the bias power for accelerating the non-oxygen gas should be 150 watts or higher, similarly to the case of using N₂-plasma, for achieving an efficient removal of the photoresist in the cylindrical holes.

The plasma ashing treatment as used in the above embodiment may be used for removal of the photoresist film for rework, which may be needed if the photoresist film embedded in the cylindrical holes has an uneven surface or has an insufficient thickness.

It may be considered that the photoresist film embedded in the cylindrical holes can be removed using a typical liquid, such as used in the conventional technique for peel-off of the photoresist. However, such a liquid should include sulfuric acid because the hardened photoresist film should be removed selectively from the underlying metal nitride film by a strong peel-off function. The sulfuric acid may damage the surface of the underlying bottom electrode, and is not preferable.

In the above embodiment, a method for forming a cylindrical capacitor is described. However, the method of the present invention may be applied to removing the photoresist in any trench on an underlying metal nitride film. The term “trench” as used herein includes a hole such as described above as a cylindrical hole used for forming therein a capacitor.

Since the above embodiment is described only for an example, the present invention is not limited to the above embodiment and various modifications or alterations can be easily made therefrom by those skilled in the art without departing from the scope of the present invention.

What is claimed is:

1. A method for manufacturing a semiconductor device comprising the steps of:
forming an insulation film on a surface of a semiconductor substrate;
forming a trench in said insulation film;
forming a metal nitride film on said insulation film including a surface of said trench;
forming a photoresist film at least within said trench on said metal nitride film;
removing a portion of said metal nitride film on said insulation film; and
removing said photoresist film by using a plasma-enhanced ashing treatment using plasma of a non-oxygen gas including therein no oxygen.

2. The method according to claim 1, wherein said non-oxygen gas includes N₂, NH₃, H₂ or a mixture of N₂ and H₂.

3. The method according to claim 1, wherein said non-oxygen gas is accelerated toward said surface of said semiconductor substrate in a direction normal thereto in said plasma-enhanced ashing treatment.

4. The method according to claim 3, wherein said non-oxygen gas is accelerated using a bias power of 150 watts or above.

5. The method according to claim 3, wherein said trench is a cylindrical hole having an aspect ratio of 15 or above.

6. The method according to claim 1, further comprising, succeeding to said photoresist removing step, the steps of cooling said semiconductor substrate down to a temperature of 100 degrees C. or lower, and exposing said metal nitride film to an atmospheric air.

7. The method according to claim 1, wherein said metal nitride film includes one of TiN, TaN and WN.

8. The method according to claim 1, further comprising, between said metal nitride forming step and said photoresist film forming step, the step of forming a metal oxide film on said metal nitride film.

9. The method according to claim 8, wherein said metal oxide film includes at least one of Al₂O₃, HfO₂, HfAlO and barium titanate.

10. The method according to claim 1, further comprising a metallic film on said insulation film, wherein said metal nitride film, said insulation film and said metallic film configure a capacitor.
